(19) United States
(12) Patent Application Publication
(10) Pub. No.: US 2013/0023103 A1
(43) Pub. Date: Jan. 24, 2013

(54) METHOD FOR FABRICATING SEMICONDUCTOR DEVICE BY USING STRESS MEMORIZATION TECHNIQUE

(71) Applicants: Chan-Lon YANG, Taipei City (TW); Ching-I LI, Tainan City (TW); Ger-Pin LIN, New Taipei City (TW)

(72) Inventors: Chan-Lon YANG, Taipei City (TW); Ching-I LI, Tainan City (TW); Ger-Pin LIN, New Taipei City (TW)

(73) Assignee: UNITED MICROELECTRONICS CORP., Hsinchu (TW)

(21) Appl. No.: 13/185,567

(22) Filed: Jul. 19, 2011

(51) Int. Cl. H01L 21/336

(52) U.S. Cl. 438/303; 257/E21.409

(57) ABSTRACT

A method for fabricating a semiconductor device is implemented by using a stress memorization technique. The method includes the following steps. Firstly, a substrate is provided, wherein a gate structure is formed over the substrate. Then, a pre-amorphization implantation process is performed to define an amorphized region at a preset area of the substrate with the gate structure serving as an implantation mask. During the pre-amorphization implantation process is performed, the substrate is controlled at a temperature lower than room temperature. Then, a stress layer is formed on the gate structure and a surface of the amorphized region. Then, a thermal treatment process is performed to re-crystallize the amorphized region of the substrate. Afterwards, the stress layer is removed.

### FIELD OF THE INVENTION

The present invention relates to a method for fabricating a semiconductor device, and more particularly to a method for fabricating a semiconductor device by using a stress memorization technique.

### BACKGROUND OF THE INVENTION

Because the length of the gate can not be limitlessly reduced any more and new materials have not been proved to be used in a metal-oxide-semiconductor field-effect transistor (MOSFET), adjusting mobility has become an important role to improve the performance of the integrated circuit. For example, the lattice strain of the channel is widely applied to increase mobility during the process of fabricating the MOSFET. For example, the hole mobility of the silicon with the lattice strain can be 4 times as many as the hole mobility of the silicon without the lattice strain, and the electron mobility with the lattice strain can be 1.8 times as many as the electron mobility of the silicon without the lattice strain.

Consequently, a tensile stress can be applied to an n-channel of an n-channel metal-oxide-semiconductor field-effect transistor (NMOS) by changing the structure of the transistor, or a compressive stress can be applied to a p-channel of a p-channel metal-oxide-semiconductor field-effect transistor (PMOS) by changing the structure of the transistor. Based on these characteristics, a stress memorization technique (SMT) is developed. However, the performance of the semiconductor device fabricating by the current stress memorization technique is still unsatisfied. Therefore, there is a need of providing an improved method for fabricating a semiconductor device by using a stress memorization technique.

### SUMMARY OF THE INVENTION

In accordance with an aspect, the present invention provides a method for fabricating a semiconductor device by using a stress memorization technique. The method includes the following steps. Firstly, a substrate is provided, wherein a gate structure is formed over the substrate. Then, a pre-amorphization implantation process is performed to define an amorphized region at a preset area of the substrate with the gate structure serving as an implantation mask. During the pre-amorphization implantation process is performed, the substrate is controlled at a temperature lower than room temperature. Then, a stress layer is formed on the gate structure and a surface of the amorphized region. Then, a thermal treatment process is performed to re-crystallize the amorphized region of the substrate. Afterwards, the stress layer is removed.

In an embodiment, the substrate is a silicon substrate.

In an embodiment, the gate structure includes a gate dielectric layer, a polysilicon gate, a hard mask layer and a spacer.

In an embodiment, the pre-amorphization implantation process is performed by doping the substrate with a dopant, and the dopant is selected from germanium, silicon, carbon, helium, neon, argon or xenon.

In an embodiment, the pre-amorphization implantation process is carried out in an ion implanter.

In an embodiment, during the pre-amorphization implantation process is performed, the substrate is controlled at a temperature lower than −100° C.

In an embodiment, the stress layer formed on the gate structure and the surface of the amorphized region is a tensile or compressive silicon nitride layer.

In an embodiment, the preset area is a source/drain region, and the source/drain region is transformed into an amorphized source/drain region by the pre-amorphization implantation process.

In an embodiment, the preset area is a lightly doped drain region, and the lightly doped drain region is transformed into an amorphized lightly doped drain region by the pre-amorphization implantation process.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1D are schematic cross-sectional views illustrating a partial process flow of a method for fabricating a semiconductor device by using a stress memorization technique according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

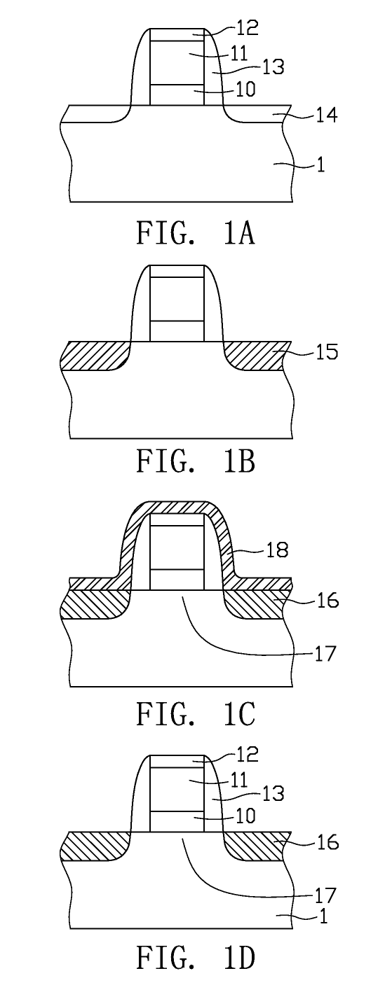

For improving the stress memorization technique, the present invention provides a method for fabricating a semiconductor device such as a metal-oxide-semiconductor field-effect transistor. FIGS. 1A˜1D are schematic cross-sectional views illustrating a partial process flow of a method for fabricating a semiconductor device by using a stress memorization technique according to an embodiment of the present invention.

Firstly, as shown in FIG. 1A, a silicon substrate 1 is provided. A gate structure including a gate dielectric layer 10, a polysilicon gate 11, a hard mask layer 12 and a spacer 13 is formed over the silicon substrate 1. In addition, a source/drain region 14 in defined in the silicon substrate 1.

Before a silicide layer is formed on a surface of the source/drain region 14, a pre-amorphization implantation process is performed to amorphize the exposed source/drain region 14 of the resulting structure of FIG. 1A. The pre-amorphization implantation process can damage the crystal lattice of the source/drain region 14, and thus the source/drain region 14 is transformed into an amorphized source/drain region 15 (see FIG. 1B). In this embodiment, the pre-amorphization implantation process is carried out after the source/drain region 14 is formed in the silicon substrate 1 and before the silicide layer is formed on the surface of the source/drain region 14. Alternatively, in some embodiments, the pre-amorphization implantation process is carried out after a lightly doped drain (LDD) region is formed. Alternatively, in some embodiments, a pre-amorphization implantation process is carried out before the silicide layer is formed on the surface of the source/drain region 14 and another pre-amorphization implantation process is carried out after a lightly doped drain (LDD) region is formed.

Then, as shown in FIG. 1C, a stress layer 18 is formed over the gate structure and the source/drain region 14 so as to provide a stress to the amorphized source/drain region 15. For example, the stress layer 18 is made of silicon nitride. In NMOS, the stress layer 18 is tensile. In PMOS, the stress layer 18 is compressive. Then, the amorphized source/drain region 15 is thermally treated at a temperature about 700° C. to 1300° C. by a soak annealing process, a spike annealing process or a millisecond annealing process, and thus the amorphized source/drain region 15 is recrystallized and transformed into a tensile or compressive source/drain region 16. Under this circumstance, since a tensile stress or a compressive stress is applied to a channel region 17, the electron mobility or the hole mobility of the channel region 17 is enhanced.

Then, the stress layer 18 is removed. The resulting structure is shown in FIG. 1D. Afterwards, the rear-end processes for producing a metal-oxide-semiconductor field-effect transistor are performed, thereby producing a metal-oxide-semiconductor field-effect transistor.

For providing more stress to the channel region 17, the depth of the amorphized source/drain region 15 should be taken into consideration. That is, if the amorphized source/drain region 15 is deepened by increasing the dopant-implanting depth, the electron mobility or the hole mobility of the channel region 17 can be further enhanced. By increasing the dopant dose and the dopant energy of performing the pre-amorphization implantation process, the dopant-implanting depth will be effectively increased. However, if the dopant energy is too high, the dopant such as tetravalent germanium, silicon, carbon or insert gas (e.g. helium, neon, argon or xenon) is possibly penetrated through the polysilicon gate 11. Under this circumstance, the gate dielectric layer 10 and the channel region 17 underlying the polysilicon gate 11 are suffered from unexpected damage.

Moreover, the method for fabricating the semiconductor device may be implemented by a gate-last technology. That is, the polysilicon gate 11 is removed in the subsequent process to create a trench, and then a metal gate is filled into the trench. In this situation, the height of the polysilicon gate 11 which is used as a dummy gate may be reduced, for example from about 800 angstroms to about <400 angstroms. Since the polysilicon gate 11 is shortened, the ability of the polysilicon gate 11 to block the dopant energy of the pre-amorphization implantation process will be impaired. Therefore, it is important to provide a method of increasing the dopant-implanting depth without damaging the gate dielectric layer 10 and the channel region 17 under the polysilicon gate 11.

The inventor found that the temperature of the silicon substrate 1 is increased during the pre-amorphization implantation process because the kinetic energy of the dopant is readily transformed into thermal energy. That is, the amorphized region is recrystallized and restored to the original crystal lattice structure. For solving these problems, the operating condition of the pre-amorphization implantation process should be modified. In accordance with the present invention, for carrying out the pre-amorphization implantation process, the silicon substrate 1 is maintained at a low temperature under room temperature. Preferably, the pre-amorphization implantation process is performed in a liquid nitrogen environment or a liquid helium environment, so that the silicon substrate 1 is maintained at a low temperature lower than −100° C. Since the temperature of the silicon substrate 1 is decreased during the pre-amorphization implantation process, the possibility of recrystallizing the amorphized region will be minimized or eliminated. In other words, the dopant-implanting depth can be effectively increased without the need of increasing the dopant energy of the pre-amorphization implantation process. Under this circumstance, the problem of damaging the gate dielectric layer 10 and the channel region 17 will be avoided. The low temperature pre-amorphization implantation process may be implemented by an ion implanter, for example an ion implanter manufactured by Varian Semiconductor Equipment Associates, Inc.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for fabricating a semiconductor device by using a stress memorization technique, the method comprising steps of:
providing a substrate, wherein a gate structure is formed over the substrate;
performing a pre-amorphization implantation process to define an amorphized region at a preset area of the substrate with the gate structure serving as an implantation mask, wherein during the pre-amorphization implantation process is performed, the substrate is controlled at a temperature lower than room temperature;
forming a stress layer on the gate structure and a surface of the amorphized region;
performing a thermal treatment process to re-crystallize the amorphized region of the substrate; and
removing the stress layer.

2. The method according to claim 1, wherein the substrate is a silicon substrate.

3. The method according to claim 1, wherein the gate structure comprises a gate dielectric layer, a polysilicon gate, a hard mask layer and a spacer.

4. The method according to claim 1, wherein the pre-amorphization implantation process is performed by doping the substrate with a dopant, and the dopant is selected from germanium, silicon, carbon, helium, neon, argon or xenon.

5. The method according to claim 1, wherein the pre-amorphization implantation process is carried out in an ion implanter.

6. The method according to claim 1, wherein during the pre-amorphization implantation process is performed, the substrate is controlled at a temperature lower than −100° C.

7. The method according to claim 1, wherein the stress layer formed on the gate structure and the surface of the amorphized region is a tensile or compressive silicon nitride layer.

8. The method according to claim 1, wherein the preset area is a source/drain region, and the source/drain region is transformed into an amorphized source/drain region by the pre-amorphization implantation process.

9. The method according to claim 1, wherein the preset area is a lightly doped drain region, and the lightly doped drain region is transformed into an amorphized lightly doped drain region by the pre-amorphization implantation process.
